(19) United States
(12) Patent Application Publication
(10) Pub. No.: US 2019/0173466 A1
(43) Pub. Date: Jun. 6, 2019

(54) Reconfigurable RF Switch using Single or Multiple-Pole, Single or Multiple-Throw Switches

(71) Applicant: pSemi Corporation, San Diego, CA (US)

(72) Inventors: Ethan Prevost, San Diego, CA (US); Dylan J. Kelly, San Diego, CA (US); Kevin Roberts, Rohnert Park, CA (US); Edward Nicholas Comfoltey, San Diego, CA (US)

(21) Appl. No.: 15/829,638

(22) Filed: Dec. 1, 2017

(51) Int. Cl. H03K 17/693

(52) U.S. Cl. CPC H03K 17/693; H01L 23/525

(57) ABSTRACT

Methods and devices taught in the present disclosure address the need for reconfigurable multi-pole multi-throw switches for various RF applications having different design requirements. Such reconfigurable switches can be reused for different applications without having to go through long research, development and manufacturing cycles. Design of multi-pole multiple switches with improved performance metric such as insertion loss, parasitic capacitance and bandwidth is also made possible using the teachings of the disclosure.

### CROSS-REFERENCE TO RELATED APPLICATIONS

The present application may be related to U.S. Pat. No. 6,804,502 issued Oct. 12, 2004, entitled “Switch circuit and method of switching radio frequency signals”, incorporated herein by reference in its entirety.

### BACKGROUND

### (1) Technical Field

The present disclosure is related to radio frequency (RF) switches, and more particularly to methods and apparatus for reconfigurable switching using single-pole single throw, single-pole multiple-throw, and/or multiple-pole multiple-throw switches.

### (2) Background

RF switches may be used as part of electronic communications and can find a wide variety of applications. For example, an M-poles N-throws (MPNT) RF switch architecture may be used in applications which require multiple transmit and/or receive paths for RF signals, particularly in order to operate in different frequency bands. Such switch architecture is useful in cellular radio systems for coupling one or more antennas to multiple sets of transmit and/or receive circuitry.

It is known to the person skilled in the art that some performance metrics of MPNTs such as insertion loss (IL), parasitic capacitance and bandwidth degrade with a higher number of throws. FIGS. 1A-1B show multiple tables and a graph, demonstrating the IL variations of a typical MPNT switch as a function of the number of throws and at different frequencies. As an example, referring to the table labeled “m7”, at a frequency of 3 GHz, the IL of a single-pole 4-throw (SP4T) is 0.187 dB. This is to be compared with a higher IL of an SP12T at the same frequency which is 0.33 dB. Also, referring back to the graph shown in FIG. 1B, it can be noticed that for the same IL, switches with lower number of throws offer a higher bandwidth. Due to the variety of applications and related requirements, immediate availability of custom designed RF switches that are tailored to specific applications is highly desired. Due to limited availability of customized designs and/or time-to-market urgency, MPNT switches with more than a required number of throws and poles are often implemented when designing systems and circuits. The main reason is that the limited existing customized designs cannot be reconfigured to serve newer and/or different applications. This results in an unnecessary additional IL and parasitic capacitances, or else for a given IL this will results in a smaller bandwidth. As an example, and for the reasons mentioned, a design requiring an SP10T may use an available SP12T instead, and the result is an overall performance degradation due to higher IL, higher parasitics or a narrower bandwidth as well as higher cost.

In line with what was described above, design companies and manufacturers are sometimes reluctant to deliver to small volume markets, the main reason being a poor return on investment. Yet some small volume markets such as police, fire and medical are critically important and demand very high performance ICs. In other words, the small size of such markets does not justify the extensive research and development efforts required to change an already available MPNT switch. It is known that integrated circuits dependent on silicon technologies have long design and fabrication cycle times. These technologies include, but are not limited to, CMOS, SOI CMOS, SOS CMOS and BiCMOS. In such cases, going after small volume is simply not economically justified for the reasons described above. Additionally, in the field of integrated circuit design, it is very common that changes are needed in final stages of product development. These changes mostly require a silicon modification, or respin, which has a prohibitively long cycle time. This simply means that either an unnecessary degradation of performance metrics has to be accepted or an unacceptable delay in delivering the product will occur due to additional required respins.

### SUMMARY

In view of what was described and in the applications where RF MPNT switches are used, there is a need for reconfigurable MPNT switches that can be used for different applications without having to go through long development and manufacturing cycles when moving from one application to another. Such reconfigurable switches, which may be reused for different applications, may improve performance metrics such as IL, parasitic capacitances or bandwidth, will drastically reduce time-to-market, and will open small-volume market opportunities to design companies and manufacturers of such switches. Methods and devices taught in the present disclosure address such need.

According to a first aspect of the present disclosure, a reconfigurable RF switch provided, comprising: a plurality of single-pole N-throw (SPNT) switches, wherein: the reconfigurable RF switch is implemented on a single die; all poles and throws of the plurality of SPNT switches are configured to be connected externally with respect to the single die; and N is an integer equal to or greater than 1.

According to a second aspect of the present disclosure, a method of building a reconfigurable RF switch on a single die is disclosed, providing: providing a plurality of single-pole N-throw (SPNT) switches on a single die, wherein poles and throws of SPNT switches of the plurality of SPNT switches are all configured to be connected externally with respect to the single die.

Further aspects of the disclosure are provided in the description, drawings and claims of the present application.

### DESCRIPTION OF THE DRAWINGS

FIG. 1A shows tables representing a typical MPNT switch IL variations vs. number of throws and at different frequencies.

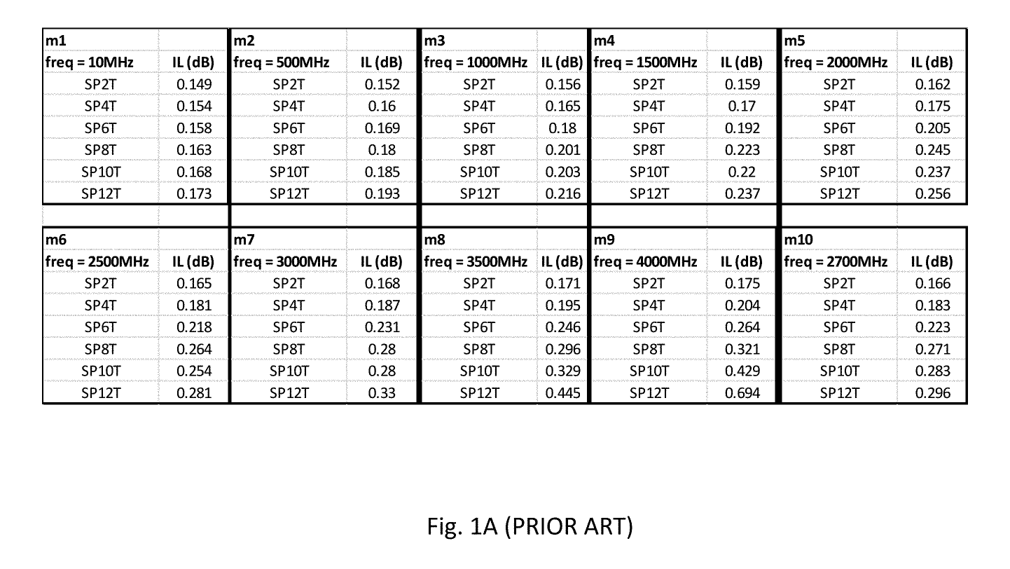

FIG. 1B shows a graph representing a typical MPNT switch IL variations vs. number of throws and at different frequencies.

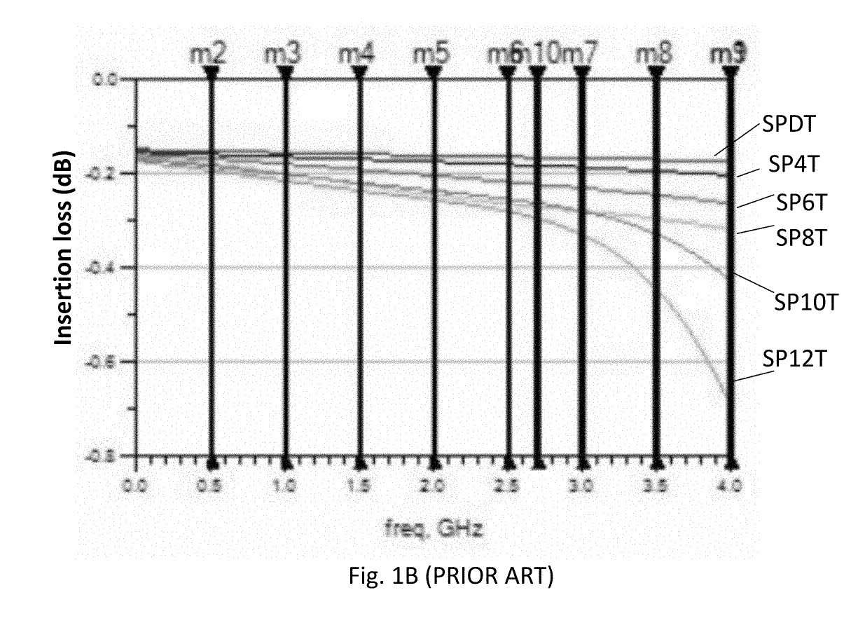

FIG. 2A shows a reconfigurable RF switch according to an embodiment of the disclosure.

FIG. 2B shows an MPNT switch with series and shunt switches.

FIG. 3A shows a reconfigurable RF switch configured to build an SP10T switch.

FIG. 3B shows a reconfigurable RF switch configured to build an SP6T, an SP4T, and an SPDT switch.

### DETAILED DESCRIPTION

Throughout this paper, the term “external connection” means off-chip connection. In other words, an integrated circuit (IC) that is “externally connectable” refers herewith to an IC having pins outside the chip and available to the user so that the pins can be externally connected according to specific design requirements. This is in contrast with a case wherein such pins are hardwired inside the chip and none or possibly only a subgrouping of them is accessible to the user.

Throughout this paper, the term “MPNT switch” refers to a multiple-pole multiple-throw switch having ‘M’ number of poles and ‘N’ number of throws wherein ‘M’ and ‘N’ are natural numbers (i.e., M=1, 2, 3, . . . and N=1, 2, 3, . . . ). The term “SPNT” switch refers to a single-pole multiple-throw switch wherein N is an integer greater than or equal to 1.

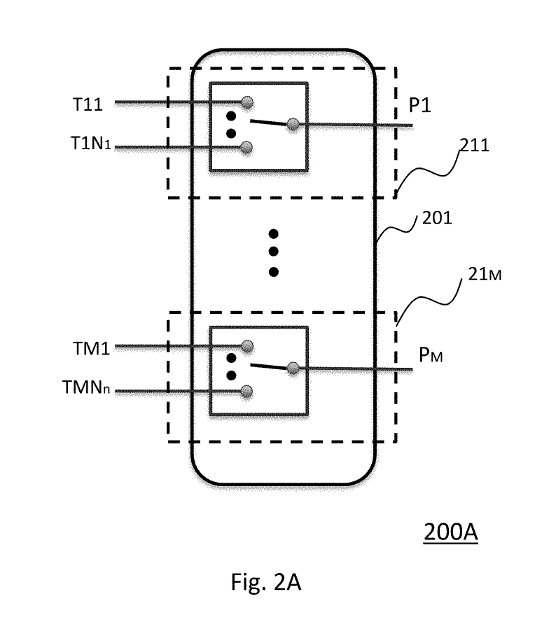

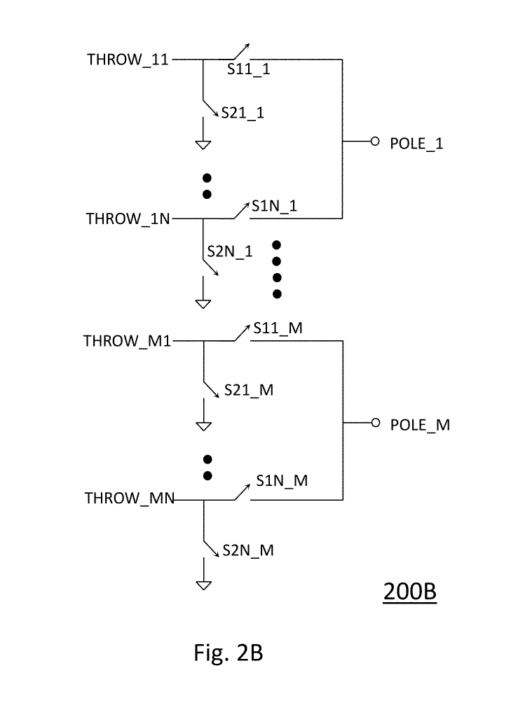

FIG. 2A shows a reconfigurable RF switch (200A) according to an embodiment of the disclosure. The reconfigurable RF switch (200A) comprises a plurality of SPNT switches (e.g., 211, . . . 21M). As an example, the SPNT switch (21M) comprises one pole and ‘Nn’ throws. In other words, the reconfigurable RF switch (200) is configurable from being M SPNT switches up to an MPNT switch with ‘M’ poles and “N=N1+ . . . Nn” throws. According to an embodiment of the disclosure, the reconfigurable RF switch (200A) is entirely implemented on a single chip or die. Also shown in FIG. 2A is a rectangle (201) representing a boundary of the single chip packaging. In other words, and according to the teachings of the disclosure, the poles and the throws of the plurality of the SPNT switches (211, . . . , 21M) are all accessible outside the chip or die such that all the poles and throws are externally connectable among themselves and/or to other devices based on specific design requirements. According to different embodiments of the disclosure, the SPNT switches (211, . . . , 21M) may have the same or different number of throws. The person skilled in the art will appreciate that, given the availability of all the poles to be connected externally to the chip or die, the reconfigurable RF switch (200A) can be used to serve various applications with different specific switching requirements. To further clarify this distinct feature of the disclosure, a few related examples will be presented later in this paper. In accordance with embodiments of the disclosure, M and Ni (i=1, 2, . . . n) may be any arbitrary natural number depending on design requirements. With continued reference to FIG. 2A and based on what described above, the building blocks of the reconfigurable switch (200A) are SPNT switches. The person skilled in the art will understand that other embodiments accordance to the teachings of the disclosure may also be considered wherein two or more poles are internally tied together. In such embodiments, the building blocks are essentially MPNT's with an arbitrary number of poles and throws.

FIG. 2B shows an MPNT switch (200B) representing an exemplary implementation of the reconfigurable RF switch (200A) of FIG. 2A. The MPNT switch (200B) comprises ‘M’ poles (e.g, POLE_1, . . . . And POLE_M) wherein each of the poles corresponds to N throws. For example, pole POLE_1 corresponds to throws (THROW_11, . . . and THROW_1N) and pole POLE_M corresponds to throws (THROW_M1, . . . and THROW_MN).

Also, shown in FIG. 2B are exemplary series and shunt switches implemented in paths connecting poles to their corresponding throws. By way of example, in a path from pole POLE_1 to throw THROW_11, there is a series switch S11_1 and a shunt switch S21_1. Similarly, in a path from pole POLE_1 to throw THROW_1N, there is a series switch S1N_1 and a shunt switch S2N_1. If pole POLE_1 is required to connect with throw THROW_11, series switch S11_1 is closed and shunt switch S21_1 is open. On the other hand, if pole POLE_1 is required to be disconnected from throw THROW_11, series switch S11_1 is open and shunt switch S21_1 is closed. Embodiments in accordance with the present disclosure may be made wherein, in one or more paths connecting any of the poles to their corresponding throws, shunt switches are not implemented. Referring to FIG. 2B and as described above, switching based on a series-shunt configuration is implemented on the paths from the poles to their corresponding throws. The person skilled in the art will understand that embodiments according to the present disclosure may be envisaged wherein a series-shunt-series configuration is implemented on paths connecting the poles to their corresponding throws. Further embodiments may also be made wherein the switching configurations from one path to another may be different.

According to an embodiment of the disclosure, the reconfigurable RF switch (200A) of FIG. 2A further comprises a control circuitry (not shown) generating control signals to open and close the series and shunt switches as described above and based on set design requirements. According to further embodiments of the disclosure, the series and shunt switches of FIG. 2B may each comprise one or a plurality of FETs or MOSFETs.

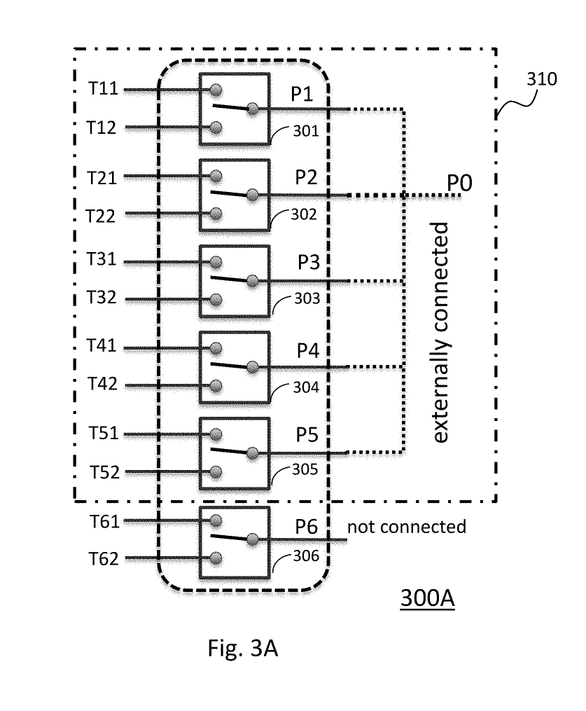

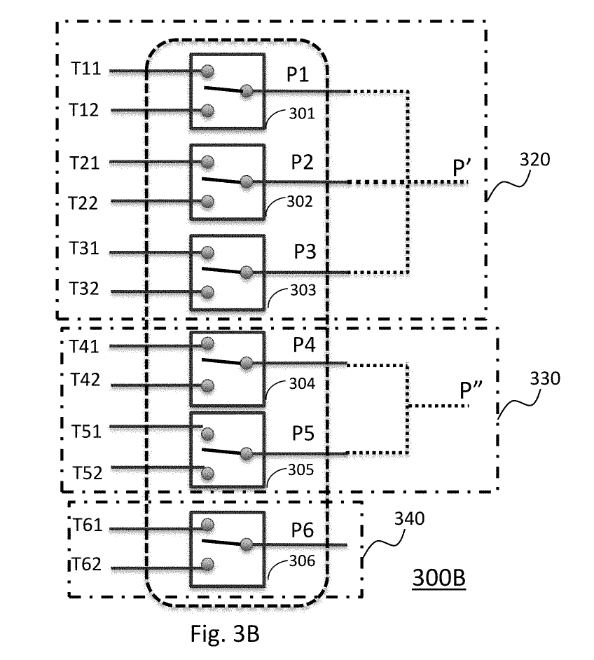

FIG. 3A shows an exemplary reconfigurable RF switch (300A) according to a further embodiment of the disclosure. The reconfigurable RF switch (300A) comprises six SPDTs (301, 302, . . . and 306) on a single die and is configured to function as an SP10T (310). In order to achieve this, the six SPDTs (301, 302, . . . and 306) have been divided into two groupings of SPDT's. One of such groupings comprises five SPDT's having poles (P1, P2, . . . and P5) wherein said poles have been connected externally together to make a single pole P0 of the SP10T (310). Throws of the five SPDTs (T11-T12, T21-T22, . . . and T51-T52) serve as the 10 throws of the designed SP10T (310). The other grouping comprises one remaining SPDT with a pole P6 and throws T61 and T62. It should be noted that the pole P6 and its corresponding throws (T61, T62) are not connected and not used. The person skilled in the art will understand that the RF switch (300A) is an exemplary embodiment wherein identical SPDT's have been implemented. Referring back to FIG. 2A, further embodiments implementing SPNT switches (with different number of throws N) other than SPDT's may also be made in accordance with the teachings of the disclosure. Based on what was described previously and in the absence of the teachings of the disclosure, it is likely that for unavailability reasons and/or time-to-market constraints, designers would end up using an existing and available SP12T (designed in accordance to the state of the art at the time of filing this application), wherein all the poles are connected on-die, i.e. internally connected. The person skilled in the art will understand that such design will have a higher insertion loss and cost as well as lower bandwidth than the SP10T (310) as described with reference to the reconfigurable RF switch (300A) of FIG. 3A; the main reason being the fact that pole P6 of the reconfigurable RF switch (300A) is not externally connected, i.e. it is not connected outside of the chip or die. In other words, by virtue of having externally connectable poles, better performance metrics are achieved. Moreover, as the original design does not need to be changed, delays in delivery of the end product due to long development and/or manufacturing cycles can be avoided. Benefits associated with the teachings of the disclosure are further highlighted below by presenting another exemplary embodiment.

In particular, FIG. 3B shows a reconfigurable RF switch (300B) which is, in terms of fundamental design, the same as the reconfigurable RF switch (300A) of FIG. 3A. However, the reconfigurable RF switch (300B) is configured differently to provide functionalities of a combination of an SP6T (320), an SP4T (330) and an SPDT (340). In order to achieve this, the six SPDT's of FIG. 3B are divided into a first grouping of three SPDT's having poles (P1, P2, P3), a second grouping of SPDT's having poles (P4, P5) and a third grouping comprising an SPDT having a pole P6. The SP6T (320) has been designed by externally tying together poles (P1, P2, P3) into a single pole P′. Pole P′ corresponds to throws (T11-T12, T21-T22, T31-T32). Similarly, by externally connecting the poles P4 and P5 into a single pole P″, the SP4T (330) is built comprising the throws (T41-T42, T51-T52). Lastly, the SPDT (340) comprises the pole P6 in correspondence with the throws (T61, T62).

Referring back to FIG. 2A, the SPNT switches (211, . . . and 21M) are basically building blocks of the reconfigurable RF switch (200A). Choosing a number of poles and throws of each of those building blocks is a matter of tradeoff between required space and flexibility. By way of example, an SP4T can be built using 2 SPDT's (requiring 6 externally connectable pins: 2 poles+4 throws) or using 4 SPST's (requiring 8 externally connectable pins: 4 poles+4 throws). Using 4 SPST's can provide more design flexibility and therefore possibility of accommodating more number of switching design requirements. However, such design may require a larger space.

With further reference to FIG. 2A and the exemplary embodiments of FIGS. 3A-3B, the person skilled in the art will appreciate that, based on the teachings of the disclosure, designing switches offering functionalities of a combination of any number of MPNT switches with arbitrary number of poles and throws is possible, as long as the reconfigurable RF switch comprises a number of poles and throws to accommodate such design. The idea is essentially to divide the plurality of SPNT switches into a plurality of groupings of SPNT switches. This step is done in accordance with set design requirements. Then poles of the SPNT switches within each subset are tied together to build the MPNT switches as required. In some embodiments, poles of one or more SPNT's of the plurality of SPNT switches may remain disconnected. Referring back to the reconfigurable RF switch (200A) of FIG. 2A, and according to further embodiments of the disclosure, two or more of the throws may be independent or tied together and/or two or more of the poles may be independent or tied together. Other embodiments according to the present teachings of the disclosure may be made to operate in broadcast mode wherein any of the poles may be configured to connect with more than one corresponding throws that are not tied together. The person skilled in the art will also appreciate that, without departing from the spirit and scope of the invention, embodiments with crossbar switching functionality may also be envisaged. In such embodiments and by way of example, one or more throws of an SPNT of FIG. 2A may be connected to one or more throws of another SPNT of FIG. 2A. As an example, one of the throws T11, . . . T1N1 of the SPNT switch (211) may be connected to one of the throws TM1, . . . , TMNn of the SPNT (21M). As a result, connection of a pole from an SPNT to throws of other SPNT's can be made possible.

Referring back to the embodiments of FIGS. 3A-3B, the person skilled in the art will appreciate that, by reusing the same chip with different configurations, substantially different MPNT switches can be produced. The following is a reiteration of substantial benefits offered by embodiments in accordance with the disclosure:
Custom design of MPNT switches with larger bandwidth or smaller IL and parasitic capacitance is made possible by reconfiguring the same and already available chip.
Long research, development and manufacturing cycles can be avoided resulting in faster time-to-market and more motivation for manufacturers to go after small-volume market opportunities.
Developing a single chip that can serve different applications with substantially different requirements is made possible.

The term “MOSFET” technically refers to metal-oxide-semiconductors; another synonym for MOSFET is “MISFET”, for metal-insulator-semiconductor FET. However, “MOSFET” has become a common label for most types of insulated-gate FETs (“IGFETs”). Despite that, it is well known that the term “metal” in the names MOSFET and MISFET is now often a misnomer because the previously metal gate material is now often a layer of polysilicon (polycrystalline silicon). Similarly, the “oxide” in the name MOSFET can be a misnomer, as different dielectric materials are used with the aim of obtaining strong channels with smaller applied voltages. Accordingly, the term “MOSFET” as used herein is not to be read as literally limited to metal-oxide-semiconductors, but instead includes IGFETs in general.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET and IGFET structures), or in hybrid or discrete circuit forms. Integrated circuit embodiments may be fabricated using any suitable substrates and processes, including but not limited to standard bulk silicon, silicon-on-insulator (SOI), silicon-on-sapphire (SOS), GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS enables low power consumption, the ability to withstand high power signals during operation due to FET stacking, good linearity, and high frequency operation (in excess of about 10 GHz, and particularly above about 20 GHz). Monolithic IC implementation is particularly useful since parasitic capacitances generally can be kept low (or at a minimum, kept uniform across all units, permitting them to be compensated) by careful design

1. A reconfigurable RF switch comprising a plurality of single-pole N-throw (SPNT) switches, wherein:
the reconfigurable RF switch is implemented on a single die;
all poles and throws of the plurality of SPNT switches are configured to be connected externally with respect to the single die;
N is an integer equal to or greater than 1;
the plurality of SPNT switches are separate with no interconnection within the single die, and
using a subset of or all of the SPNT switches of the plurality of SPNT switches, the reconfigurable RF switch is reconfigurable to operate as one or more of a) a plurality of single-pole, single-throw switches, b) a plurality of multiple-pole, multiple-throw switches and c) a combination thereof.

2. The reconfigurable RF switch of claim 1, wherein at least one of the SPNT switches of the plurality of SPNT switches has a number of throws that is different from a number of throws of the other SPNT switches of the plurality of SPNT switches.

3. The reconfigurable RF switch of claim 1, wherein all of the SPNT switches of the plurality of SPNT switches have a same number of throws.

4. The reconfigurable RF switch of claim 2, wherein each of the SPNT switches of the plurality of SPNT switches has a number of throws that is different from the number of throws of any one of the other SPNT switches of the plurality of SPNT switches.

5. The reconfigurable RF switch of claim 1, wherein each of the plurality of SPNT switches is a single-pole single-throw (SPST) switch.

6. The reconfigurable RF switch of claim 1, wherein each of the plurality of SPNT switches is a single-pole double-throw (SPDT) switch.

7. The reconfigurable RF switch of claim 6, wherein the plurality of SPNT switches comprises a number N1 of SPDT switches and wherein poles of (N1-1) of the SPDT switches are externally connected to one another to build an SP(2N1-2)T switch and wherein a pole of a remaining SPDT switch remains disconnected.

8. The reconfigurable RF switch of claim 6, wherein the plurality of SPNT switches comprises six SPDT switches and wherein:
poles of a first, a second and a third SPDT switch of the plurality of SPNT switches are externally connected to one other, and
poles of a fourth and a fifth SPDT switch of the plurality of SPNT switches are externally connected to each other;
thereby generating an M-pole N-throw (MPNT) switch comprising an SP6T, an SP4T and an SPDT switch.

9. The reconfigurable RF switch of claim 1, wherein each SPNT switch of the plurality of SPNT switches comprises series and shunt switches.

10. The reconfigurable RF switch of claim 9, further comprising a control circuitry providing control signals to turn the series and shunt switches ON or OFF.

11. The reconfigurable RF switch of claim 9, wherein each of the series and shunt switches comprises one or a plurality of FET or MOSFET transistors.

12. A method of building a reconfigurable RF switch on a single die, the method comprising the steps of:
providing a plurality of single-pole N-throw (SPNT) switches on the single die, and
using a subset of or all of the SPNT switches of the plurality of SPNT switches, to reconfigure the reconfigurable RF switch to operate as one or more of a) a plurality of single-pole, single-throw switches, b) a plurality of multiple-pole, multiple-throw switches and c) a combination thereof;
wherein poles and throws of SPNT switches of the plurality of SPNT switches are all configured to be connected externally with respect to the single die, and wherein the plurality of SPNT switches are separate with no interconnection within the die.

13. The method of building a reconfigurable RF switch on a single die of claim 12, wherein at least one of the SPNT switches of the plurality of SPNT switches has a different number throws from at least one other of the SPNT switches.

14. The method of building a reconfigurable RF switch on a single die of claim 12, wherein the plurality of SPNT switches are all the same.

15. The method of building a reconfigurable RF switch on a single die of claim 12, wherein each of the plurality of SPNT switches is either single-pole single-throw (SPST) switch or single-pole double-throw (SPDT) switch.

16. A method of configuring the reconfigurable RF switch of claim 1, the method comprising steps of:
dividing the the plurality of SPNT switches into a plurality of groupings of SPNT switches, and
within each grouping of the plurality of groupings of SPNT switches, externally connecting poles of the SPNT switches of the each grouping of the plurality of groupings of SPNT switches to one another.

17. The method of claim 16, wherein poles of at least one SPNT switches of the plurality of SPNT switches remains disconnected externally with respect to the single die.

18. The reconfigurable RF switch of claim 7, wherein N1 is six.
